(19) United States
(12) Patent Application Publication
(10) Pub. No.: US 2025/0338757 A1
(43) Pub. Date: Oct. 30, 2025

(54) DISPLAY SUBSTRATE, METHOD OF MANUFACTURING DISPLAY APPARATUS, AND METHOD OF MANUFATURING ELECTRONIC APPARATUS

(71) Applicant: Samsung Display Co., LTD., Yongin-si (KR)

(72) Inventors: Seungwook Kwon, Yongin-si (KR); Sangtae Ahn, Yongin-si (KR); Heechang Yoon, Yongin-si (KR); Changwoo Shim, Yongin-si (KR); Yejoo Jun, Yongin-si (KR)

(21) Appl. No.: 19/195,393

(22) Filed: Apr. 30, 2025

(30) Foreign Application Priority Data
Apr. 30, 2024 (KR) 10-2024-0058130

(51) Int. Cl. H10K 59/80; H10K 59/12

(52) U.S. Cl. CPC H10K 59/873; H10K 59/1201

(57) ABSTRACT

A display substrate includes a substrate including a display area and a peripheral area surrounding the display area, a plurality of light-emitting diodes in the display area over the substrate, a thin-film encapsulation layer covering the plurality of light-emitting diodes, and a plurality of protrusions arranged in the peripheral area on the thin-film encapsulation layer and arranged along at least a portion of edges of the display area.

This application claims priority to Korean Patent Application Nos. 10-2024-0058130, filed on Apr. 30, 2024, and all the benefits accruing therefrom under 35 U.S.C. § 119, the content of which in its entirety is herein incorporated by reference.

### BACKGROUND

### 1. Field

One or more embodiments relate to a display substrate and a method of manufacturing a display apparatus. One or more embodiments relate to a method of manufacturing an electronic apparatus.

### 2. Description of the Related Art

An electronic apparatus may include a display apparatus to display image or/and video. A display apparatus may include light-emitting diodes (LEDs), for example, organic light-emitting diodes (OLEDs). A protective film may be attached to a semi-finished product (hereinafter, referred to as a ‘display substrate’) of a display apparatus undergoing a manufacturing process to protect a surface of the display substrate during the manufacturing process. The protective film may be disposed on the display substrate in a solid state or in a liquid state and then solidified (or hardened). Unlike solid protective films that have a certain shape, liquid (or resin) protective films may be applied on display substrates of various shapes because liquid (or resin) protective films may flow freely on a display substrate.

### SUMMARY

A process of disposing a liquid (or resin) protective film may include disposing a resin on a display substrate, flowing the resin as much as an area to be covered, and curing the resin into a solid state. In this process, when the resin flows, the resin may overflow beyond a boundary of the area to be covered, and when the resin is cured, the resin may shrink and create an area that may not be covered. As described above, in the case of using a liquid (or resin) protective film, it may be difficult to control the area where the film is formed. Therefore, a structure that may match the area to be covered and the area where the film is actually formed is desired.

According to one or more embodiments, a display substrate includes a substrate including a display area and a peripheral area surrounding the display area, a plurality of light-emitting diodes arranged in the display area over the substrate, a thin-film encapsulation layer covering the plurality of light-emitting diodes, and a plurality of protrusions arranged in the peripheral area on the thin-film encapsulation layer, where the plurality of protrusions are arranged along at least a portion of edges of the display area.

In an embodiment, the display substrate may further include a resin disposed on the thin-film encapsulation layer and overlapping the display area.

In an embodiment, the resin may be in direct contact with at least one of the plurality of protrusions.

In an embodiment, the plurality of protrusions may be apart from each other, and a portion of an edge of the resin may be between two adjacent protrusions among the plurality of protrusions.

In an embodiment, the substrate may include an opening area inside the display area and an intermediate area between the opening area and the display area, where the intermediate area at least partially may surround the opening area, and the display substrate may further include a plurality of protrusions disposed on the thin-film encapsulation layer in the intermediate area.

In an embodiment, the display substrate may further include an input-sensing layer disposed on the thin-film encapsulation layer and including an electrode layer and an insulating layer, where the plurality of protrusions may be disposed on the input-sensing layer.

In an embodiment, the thin-film encapsulation layer may include a first inorganic encapsulation layer covering the plurality of light-emitting diodes, an organic encapsulation layer disposed on the first inorganic encapsulation layer, and a second inorganic encapsulation layer covering the organic encapsulation layer.

In an embodiment, the plurality of protrusions may be arranged outside a region in which the organic encapsulation layer is arranged.

According to one or more embodiments, a method of manufacturing a display apparatus includes preparing a display substrate including a plurality of light-emitting diodes arranged in a display area, and a thin-film encapsulation layer covering the plurality of light-emitting diodes, disposing a plurality of protrusions on the thin-film encapsulation layer in a peripheral area surrounding the display area, and disposing a resin on the display substrate to overlap the display area.

In an embodiment, the plurality of protrusions may be arranged along an edge of the display area.

In an embodiment, the plurality of protrusions may be apart from each other.

In an embodiment, the method may further include causing the resin to flow toward the plurality of protrusions.

In an embodiment, an edge of a region in which the resin is arranged may be defined by the plurality of protrusions.

In an embodiment, the method may further include curing the resin.

In an embodiment, during the curing of the resin, the edge of the region in which the resin is arranged may be fixed and maintained by the plurality of protrusions.

In an embodiment, the method may further include separating the cured resin together with at least one of the plurality of protrusions from the display substrate.

In an embodiment, the display substrate may include an opening area inside the display area and an intermediate area between the opening area and the display area, the intermediate area at least partially surrounding the opening area, where the method may further include disposing a plurality of additional protrusions on the thin-film encapsulation layer in the intermediate area.

In an embodiment, the method may further include disposing an input-sensing layer on the thin-film encapsulation layer, where the disposing the plurality of protrusions may include disposing the plurality of protrusions on the input-sensing layer on the thin-film encapsulation layer.

In an embodiment, the thin-film encapsulation layer may include a first inorganic encapsulation layer covering the plurality of light-emitting diodes, an organic encapsulation layer disposed on the first inorganic encapsulation layer, and a second inorganic encapsulation layer covering the organic encapsulation layer.

In an embodiment, the plurality of protrusions may be arranged outside a region in which the organic encapsulation layer is arranged.

According to one or more embodiments, a method of manufacturing an electronic apparatus includes manufacturing a display apparatus and disposing the display apparatus in a housing, wherein manufacturing the display apparatus includes preparing a display substrate including a plurality of light-emitting diodes arranged in a display area and a thin-film encapsulation layer covering the plurality of light-emitting diodes, disposing a plurality of protrusions on the thin-film encapsulation layer in a peripheral area surrounding the display area, and disposing a resin on the display substrate to overlap the display area.

In an embodiment, the method may further include disposing an electronic element in the housing.

### BRIEF DESCRIPTION OF THE DRAWINGS

The above and other features of certain embodiments of the disclosure will be more apparent from the following description taken in conjunction with the accompanying drawings, in which:

FIG. 1 is a schematic plan view of an electronic apparatus according to an embodiment;

FIG. 2 is a schematic cross-sectional view of the electronic apparatus taken along line II-II′ of FIG. 1, according to an embodiment;

FIG. 3 is a schematic plan view of a display substrate according to an embodiment;

FIG. 4 is a schematic cross-sectional view of the display substrate taken along line IV-IV′ of FIG. 3, according to an embodiment;

FIG. 5 is an enlarged plan view showing a portion of the display substrate according to an embodiment and an enlarged plan view of a region V of FIG. 3;

FIG. 6 is an enlarged plan view showing a portion of the display substrate according to an embodiment and an enlarged plan view of a region VI of FIG. 3;

FIG. 7 is a cross-sectional view showing a portion of the display substrate according to an embodiment and is a cross-sectional view of the display substrate taken along line VII-VII′ of FIG. 6;

FIG. 8 is an enlarged plan view showing a portion of a display substrate according to an embodiment and an enlarged plan view of a region VIII of FIG. 3;

FIG. 9 is a cross-sectional view showing a portion of the display substrate according to an embodiment and is a cross-sectional view of the display substrate taken along line IX-IX′ of FIG. 8;

FIGS. 10A, 10B, 10C, 10D, 10E, and 10F are perspective views of protrusions according to various embodiments;

FIGS. 11A, 11B, 11C, and 11D are plan views showing various examples in which the protrusions may be arranged in a corner region;

FIG. 12 is an enlarged plan view of a portion of a display substrate according to an embodiment and shows an embodiment in which resin is provided to the embodiment shown in FIG. 5;

FIG. 13 is an enlarged plan view of a portion of a display substrate according to an embodiment and shows an embodiment in which resin is provided to the embodiment shown in FIG. 6;

FIG. 14 is an enlarged plan view of a portion of a display substrate according to an embodiment and shows an embodiment in which resin is provided to the embodiment shown in FIG. 8; and

FIGS. 15A, 15B, 15C, 15D, 15E, 15F, and 15G are schematic perspective views showing operations of a process of manufacturing a display apparatus according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b or c” indicates only a, only b, only c, both a and b, both a and c, both b and c, all of a, b, and c, or variations thereof.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In the case where a certain embodiment may be implemented differently, a specific process order may be performed in the order different from the described order. As an example, two processes successively described may be simultaneously performed substantially and performed in the opposite order.

In the present specification, “A and/or B” means A or B, or A and B. In the present specification, “at least one of A and B” means A or B, or A and B.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be perpendicular to one another or may represent different orientations that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

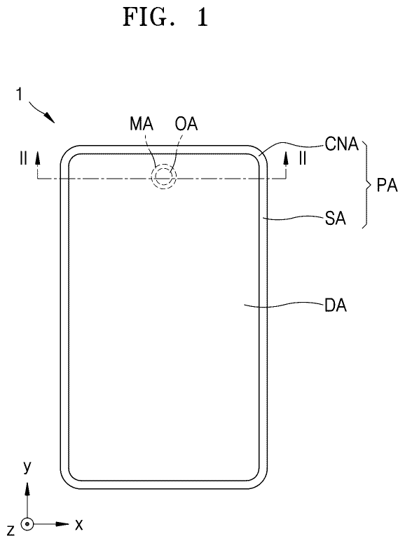

FIG. 1 is a schematic plan view of an electronic apparatus 1 according to an embodiment.

Referring to FIG. 1, an embodiment of the electronic apparatus 1 may include an apparatus for displaying moving images or still images and may be used as a display screen of various products including televisions, notebook computers, monitors, advertisement boards, Internet of things (IoTs) as well as portable electronic apparatuses including mobile phones, smartphones, tablet personal computers (PCs), mobile communication terminals, electronic organizers, electronic books, portable multimedia players (PMPs), navigations, and ultra mobile personal computers (UMPCs). In addition, the electronic apparatus 1 may be used in wearable devices including smartwatches, watchphones, glasses-type displays, and head-mounted displays (HMDs). In addition, in an embodiment, the electronic apparatus 1 may be used as a display in instrument panels for automobiles, center fascias for automobiles, or center information displays (CIDs) arranged on a dashboard, mirror displays that replace side mirrors of automobiles, and displays of an entertainment system arranged on the backside of front seats for backseat passengers in automobiles. For convenience of illustration and description, FIG. 1 shows an embodiment where the electronic apparatus 1 is used as a smartphone.

In an embodiment, the electronic apparatus 1 may have an approximate rectangular shape in a plan view or when viewed in a z direction (i.e., the z-axis direction). In an embodiment, for example, as shown in FIG. 1, the electronic apparatus 1 may have a quadrangular shape having short sides in an x direction (i.e., the x-axis direction) and long sides in a y direction (i.e., the y-axis direction) in a plan view. Edges where short sides in the x direction meet long sides in the y direction may be rounded to have a preset curvature as shown in FIG. 1 or formed at right angles. A planar shape of the electronic apparatus 1 is not limited to a rectangle, but may be other polygons, ellipses, or irregular shapes.

The electronic apparatus 1 may include an opening area OA and a display area DA partially surrounding the opening area OA. The electronic apparatus 1 may include an intermediate area MA and a peripheral area PA, where the intermediate area MA is arranged between the opening area OA and the display area DA, and the peripheral area PA surrounds the outer side of the display area DA. The intermediate area MA may have a closed loop shape entirely surrounding the opening area OA in a plan view.

The opening area OA may be located (or defined) inside the display area DA. In an embodiment, the opening area OA may be arranged on the upper center of the display area DA as shown in FIG. 1. Alternatively, the opening area OA may be arranged on the upper left side of the display area DA, or the upper right side of the display area DA. However, the opening area OA may be arranged on various positions. Although FIG. 1 shows an embodiment where a single opening area OA is arranged, a plurality of opening areas OA may be arranged in another embodiment.

The peripheral area PA may include side areas SA respectively corresponding to the sides of the electronic apparatus 1. The side area SA may be an area corresponding to a short side or long side of the electronic apparatus 1 extending in, for example, the x direction or y direction. The side area SA may also extend in the x direction or y direction.

The peripheral area PA may include a corner area CNA corresponding to the corner of the electronic apparatus 1. The long and short sides of the electronic apparatus 1 may meet each other at the corner of the electronic apparatus 1. The corner area CNA may be an area corresponding to the corner. In an embodiment, the corner area CNA may correspond to a rounded area of the electronic apparatus 1. In an embodiment, the corner area CNA may be located between two adjacent side areas SA, and the side area SA may be located between two corner areas CNA.

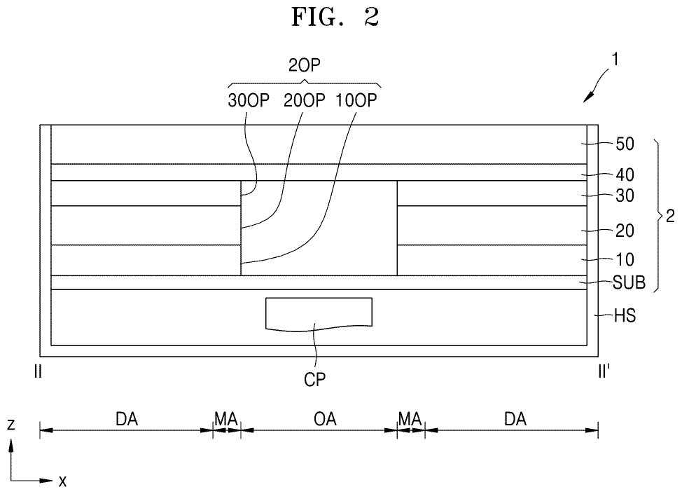

FIG. 2 is a schematic cross-sectional view of the electronic apparatus 1 taken along line II-II′ of FIG. 1, according to an embodiment.

Referring to FIG. 2, an embodiment of the electronic apparatus 1 may include a display apparatus 2 and a component CP disposed in the opening area OA of the display apparatus 2. The display apparatus 2 and the component CP may be disposed or received in a housing HS.

The display apparatus 2 may include a substrate SUB, an image generating layer 10, an input-sensing layer 20, an optical functional layer 30, an adhesive layer 40, and a cover window 50.

The image generating layer 10 may include display elements configured to emit light to display images. The display element may include a light-emitting diode, for example, an organic light-emitting diode including an organic emission layer. In another embodiment, the light-emitting diode may be an inorganic light-emitting diode including an inorganic material. The inorganic light-emitting diode may include a PN-junction diode including inorganic material semiconductor-based materials. When a forward voltage is applied to a PN-junction diode, holes and electrons are injected and energy created by recombination of the holes and the electrons is converted to light energy, and thus, light of a preset color may be emitted. The inorganic light-emitting diode may have a width of several micrometers to hundreds of micrometers, or several nanometers to hundreds of nanometers. In an embodiment, the image generating layer 10 may include a quantum-dot light-emitting diode. In an embodiment, for example, an emission layer of the image generating layer 10 may include an organic material, an inorganic material, quantum dots, an organic material and quantum dots, or an inorganic material and quantum dots.

The input-sensing layer 20 may be configured to obtain coordinate information corresponding to an external input, for example, a touch event. The input-sensing layer 20 may include a sensing electrode (or a touch electrode) and trace lines connected to the touch electrode. The input-sensing layer 20 may be disposed on the image generating layer 10. The input-sensing layer 20 may sense an external input by using a self-capacitance method and/or a mutual capacitance method.

The input-sensing layer 20 may be directly formed on the image generating layer 10, or separately formed and then coupled to the image generating layer 10 by using an optically clear adhesive. In an embodiment, for example, the input-sensing layer 20 may be successively formed after a process of forming the image generating layer 10. In such an embodiment, an adhesive layer may not be disposed between the input-sensing layer 20 and the image generating layer 10. Although FIG. 2 shows an embodiment where the input-sensing layer 20 is disposed between the image generating layer 10 and the optical functional layer 30, the input-sensing layer 20 may be disposed on the optical functional layer 30 in another embodiment.

The optical functional layer 30 may include an anti-reflection layer. The anti-reflection layer may reduce the reflectivity of light (external light) incident toward the display apparatus 2 from the outside through the cover window 50. In an embodiment, the anti-reflection layer may include a phase retarder and a polarizer. In another embodiment, the anti-reflection layer may include a black matrix and color filters. The color filters may be arranged based on an arrangement of colors of light emitted respectively from the light-emitting diodes of the image generating layer 10.

The display apparatus 2 may be provided with an opening 20P defined or formed through a portion of layers constituting or forming the display apparatus 2 to improve a transmittance of the opening area OA. The opening 20P may include first to third openings 100P, 200P, and 300P respectively defined or formed through the image generating layer 10, the input-sensing layer 20, and the optical functional layer 30. The opening 100P of the image generating layer 10, the opening 200P of the input-sensing layer 20, and the opening 300P of the optical functional layer 30 may overlap each other to collectively form the opening 20P of the display apparatus 2.

The cover window 50 may be disposed on the optical functional layer 30. The cover window 50 may be coupled to the optical functional layer 30 by an adhesive layer 40 such as a transparent optical clear adhesive (OCA) disposed between the cover window 50 and the optical functional layer 30. The cover window 50 may cover the opening 100P of the image generating layer 10, the opening 200P of the input-sensing layer 20, and the opening 300P of the optical functional layer 30.

The cover window 50 may include a glass material or a plastic material. The glass material may include ultra thin Glass®. The plastic material may include polyethersulfone, polyacrylate, polyetherimide, polyethylene naphthalate, polyethylene terephthalate, polyphenylene sulfide, polyarylate, polyimide, polycarbonate, or cellulose acetate propionate.

The opening area OA may be a kind of component area (e.g., a sensor region, a camera region, a speaker region, and the like) in which the component CP for adding various functions to the electronic apparatus 1 is located.

The component CP may include an electronic element. In an embodiment, for example, the component CP may be an electronic element that uses light or sound. In an embodiment, for example, the electronic element may include a sensor such as an infrared sensor that uses light, a camera that receives light to capture an image, a sensor that outputs and senses light or sound to measure a distance or recognize a fingerprint, a small lamp that outputs light, and a speaker that outputs sound. The electronic element that uses light may use light in various wavelength bands such as visible light, infrared light, ultraviolet light and the like. The opening area OA corresponds to an area through which light and/or sound output from the component CP to the outside or progressing toward the electronic element from the outside may pass.

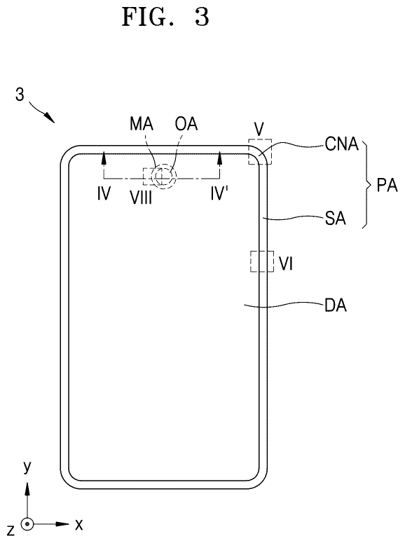

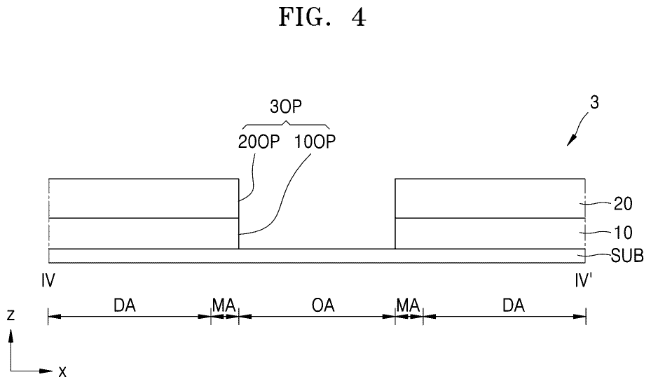

FIG. 3 is a schematic plan view of a display substrate 3 according to an embodiment. FIG. 4 is a schematic cross-sectional view of the display substrate 3, taken along line IV-IV′ of FIG. 3, according to an embodiment.

In the disclosure, the display substrate 3 may denote a semi-finished product undergoing the process of manufacturing the display apparatus 2. The display substrate 3 may not include some of elements of the display apparatus 2. For example, referring to FIGS. 2 and 4 together, the display apparatus 2 may include the optical functional layer 30, the adhesive layer 40, and the cover window 50, while the display substrate 3 may not include these elements. In other words, the display substrate 3 may include the image generating layer 10 and the input-sensing layer 20 during the manufacturing of the display apparatus 2, and may be in a state before the optical functional layer 30 is provided or formed on the input-sensing layer 20. This is provided as an example and the disclosure is not limited to the configuration of only these specific layers.

Referring to FIG. 3, similar to the electronic apparatus 1 (see FIG. 1), the display substrate 3 may include the display area DA, the peripheral area PA, the corner area CNA, the side area SA, the opening area OA, and the intermediate area MA. In an embodiment, the shape of the display substrate 3 may be similar to the shape of the electronic apparatus 1 (see FIG. 1) in a plan view.

Referring to FIG. 4, an embodiment of the display substrate 3 may include the substrate SUB, the image generating layer 10, and the input-sensing layer 20. The image generating layer 10 may be disposed on the substrate SUB, and the input-sensing layer 20 may be disposed on the image generating layer 10. Each of a portion of the image generating layer 10 and a portion of the input-sensing layer 20 may be open. The opening 30P of the display substrate 3 may include the opening 100P of the image generating layer 10 and the opening 200P of the input-sensing layer 20.

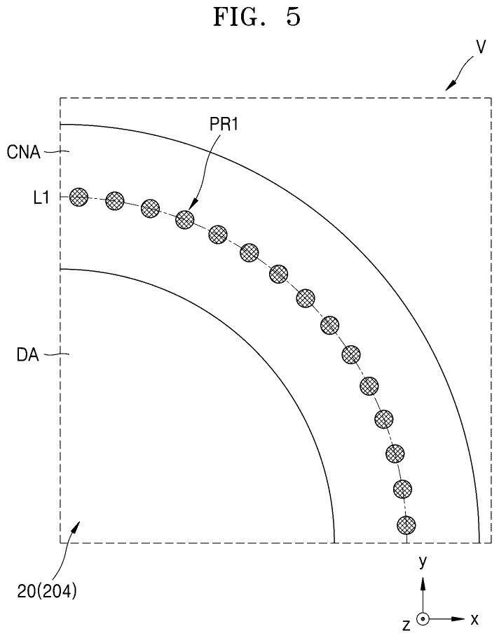

FIG. 5 is an enlarged plan view of a portion of the display substrate 3 according to an embodiment, and an enlarged plan view of a region V of FIG. 3.

In FIG. 5, the corner area CNA of the display substrate 3 (see FIG. 3) is enlargedly shown. In an embodiment, as shown in FIG. 5, a plurality of first protrusions PR1 may be arranged in the corner area CNA. In an embodiment, each of the first protrusions PR1 may be circular in a plan view. The disclosure is not limited to the shape of the first protrusions PR1 shown in FIG. 5, and the shape of the first protrusions PR1 may be variously modified as described below.

In an embodiment, the first protrusions PR1 may be arranged along an imaginary line, for example, a first line L1. In an embodiment, for example, the center of each of the first protrusions PR1 may be located on the first line L1. In an embodiment, the first line L1 may be a curved line extending along (or in a same direction as) the circumference of the round corner area CNA. In an embodiment, for example, the first line L1 may have an arc shape having a radius greater than the radius of the round corner of the display area DA and less than the radius of the round corner area CNA. In other words, the first line L1 may be located between the boundary of the display area DA and the corner area CNA, and the outer edge of the corner area CNA. Accordingly, the first protrusions PR1 may be also located between the boundary of the display area DA and the corner area CNA, and the outer edge of the corner area CAN, that is, located within the corner area CNA. Although only one first line L1 is shown in FIG. 5, the disclosure is not limited thereto, and there may be a plurality of imaginary lines on which the first protrusions PR1 are arranged.

The first protrusions PR1 may be disposed on the input-sensing layer 20. In an embodiment, for example, the input-sensing layer 20 may include a second touch insulating layer 204, and the first protrusions PR1 may be disposed on the second touch insulating layer 204.

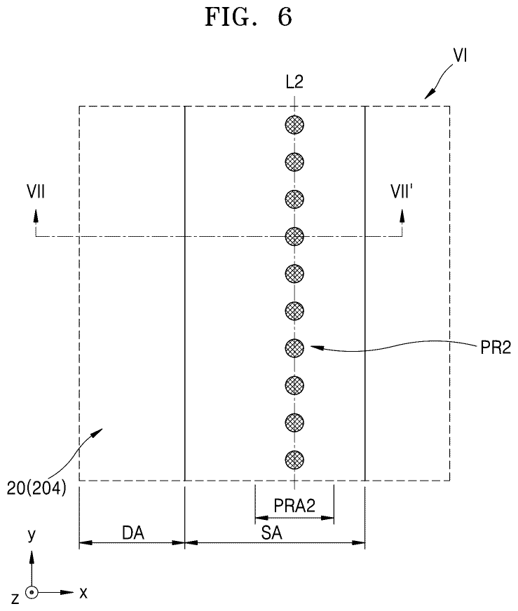

FIG. 6 is an enlarged plan view of a portion of the display substrate 3 according to an embodiment, and an enlarged plan view of a region VI of FIG. 3.

In FIG. 6, the side area SA of the display substrate 3 (see FIG. 3) is enlargedly shown. Hereinafter, although description is made based on the side area SA of the display substrate 3 (see FIG. 3) in a +x direction, this is for convenience of description, and the following described features are applicable to each of the side areas SA of the display substrate 3 (see FIG. 3) in a +y direction, a −y direction, and a −x direction.

A plurality of second protrusions PR2 may be arranged in the side area SA. In an embodiment, each of the second protrusions PR2 may be circular in a plan view. The disclosure is not limited to the shape of the second protrusions PR2, and the shape of the second protrusions PR2 may be variously modified as described below.

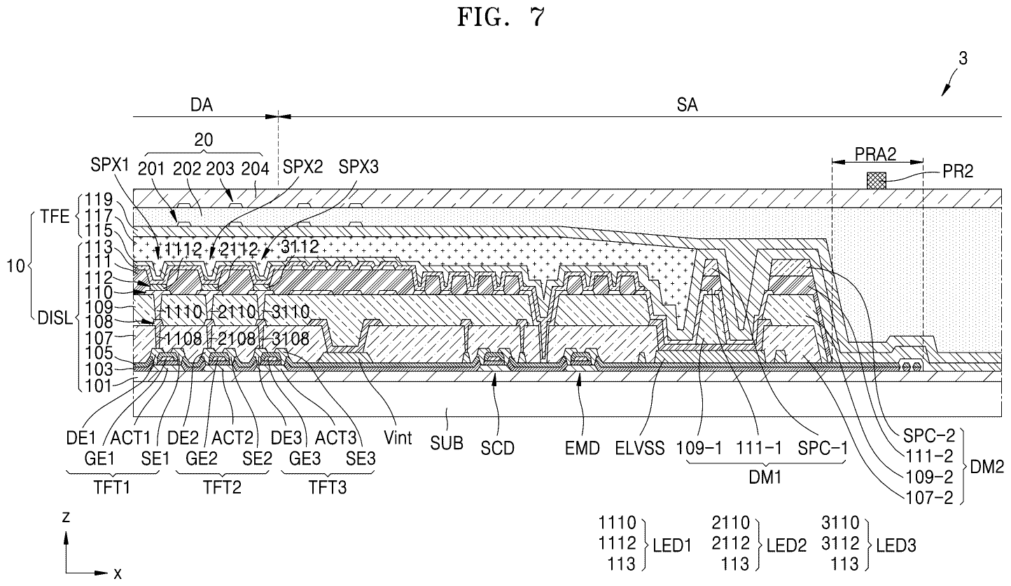

In an embodiment, the second protrusions PR2 may be arranged along an imaginary line, for example, a second line L2. In an embodiment, for example, the center of the second protrusion PR2 may be located on the second line L2. In an embodiment, the second line L2 may be a straight line extending in a direction in which the side area SA extends. In an embodiment, for example, as shown in FIG. 6, the side area SA and the second line L2 may extend in a y axis. In another area, for example, in an area in which the side area SA extends along the x axis, the second line L2 may extend in the x axis. The second protrusions PR2 may be arranged between the boundary of the display area DA and the side area SA, and the outer edge of the side area SA. In an embodiment, the second protrusions PR2 may be arranged in a preset area inside the side area SA, for example, arranged within a second protrusion area PRA2. The second protrusion area PRA2 is described below with reference to FIG. 7. Although only one second line L2 is shown in FIG. 6, the disclosure is not limited thereto, and there may be a plurality of imaginary lines on which the second protrusions PR2 are arranged.

The second protrusions PR2 may be disposed on the input-sensing layer 20. In an embodiment, for example, the input-sensing layer 20 may include the second touch insulating layer 204, and the second protrusions PR2 may be disposed on the second touch insulating layer 204.

FIG. 7 is a cross-sectional view of a portion of the display substrate 3 according to an embodiment and is a cross-sectional view of the display substrate 3, taken along line VII-VII′ of FIG. 6.

Referring to FIG. 7, in an embodiment, the image generating layer 10 may include a display element layer DISL and a thin-film encapsulation layer TFE, where the display element layer DISL includes display elements, and the thin-film encapsulation layer TFE encapsulates and protects the display element layer DISL. The input-sensing layer 20 is disposed on the image generating layer 10, where the input-sensing layer 20 is configured to receive a user's input (e.g., a touch).

The display element layer DISL including various layers described below may be disposed on the substrate SUB.

A plurality of sub-pixels, which are display elements, may be arranged in the display area DA. Each of the sub-pixels may include a corresponding light-emitting diode and a corresponding thin-film transistor. In an embodiment, for example, in the display area DA, a first sub-pixel SPX1, and a first light-emitting diode LED1 and a first thin-film transistor TFT1 corresponding thereto, a second sub-pixel SPX2, and a second light-emitting diode LED2 and a second thin-film transistor TFT2 corresponding thereto, and a third sub-pixel SPX3, and a third light-emitting diode LED3 and a third thin-film transistor TFT3 corresponding thereto may be arranged. The first light-emitting diode LED1, the second light-emitting diode LED2, and the third light-emitting diode LED3 may be configured to respectively emit light of different colors. In an embodiment, the first light-emitting diode LED1 may be configured to emit blue light, the second light-emitting diode LED2 may be configured to emit green light, and the third light-emitting diode LED3 may be configured to emit red light.

A buffer layer 101 may be disposed on the substrate SUB. The buffer layer 101 may protect the upper surface of the substrate SUB while planarizing the upper surface of the substrate SUB. The buffer layer 101 may include an inorganic insulating material such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂), and have a single layer or a multi-layered structure, each layer therein including at least one selected from the above materials.

The first thin-film transistor TFT1, the second thin-film transistor TFT2, and the third thin-film transistor TFT3 may be disposed on the buffer layer 101. Each thin-film transistor may be connected to a corresponding light-emitting diode to drive the light-emitting diode. The first thin-film transistor TFT1 may include a first active layer ACT1, a first gate electrode GE1, a first source electrode SE1, and a first drain electrode DE1. The second thin-film transistor TFT2 may include a second active layer ACT2, a second gate electrode GE2, a second source electrode SE2, and a second drain electrode DE2. The third thin-film transistor TFT3 may include a third active layer ACT3, a third gate electrode GE3, a third source electrode SE3, and a third drain electrode DE3.

The first active layer ACT1, the second active layer ACT2, and the third active layer ACT3 may be apart from each other on the buffer layer 101 in a plan view or when viewed in the z direction. Here, the z direction may be a thickness direction of the substrate SUB or the display substrate 3. The first active layer ACT1 may include a drain region overlapping the first drain electrode DE1, a source region overlapping the first source electrode SE1, and a channel region between the drain region and the source region. The second active layer ACT2 may include a drain region overlapping the second drain electrode DE2, a source region overlapping the second source electrode SE2, and a channel region between the drain region and the source region. The third active layer ACT3 may include a drain region overlapping the third drain electrode DE3, a source region overlapping the third source electrode SE3, and a channel region between the drain region and the source region. Each of the drain region and the source region may be a region doped with impurities.

A gate insulating layer 103 may cover the first active layer ACT1, the second active layer ACT2, and the third active layer ACT3. The gate insulating layer 103 may include an inorganic insulating material such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂), and have a single layer or a multi-layered structure, each layer therein including at least one selected from the above materials.

The first gate electrode GE1, the second gate electrode GE2, and the third gate electrode GE3 may be disposed on the gate insulating layer 103. Each gate electrode may overlap a channel region of the corresponding active layer. In an embodiment, for example, the first gate electrode GE1 may overlap a channel region of the first active layer ACT1, the second gate electrode GE2 may overlap a channel region of the second active layer ACT2, and the third gate electrode GE3 may overlap a channel region of the third active layer ACT3. The first gate electrode GE1, the second gate electrode GE2, and the third gate electrode GE3 may include aluminum (AI), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layered structure, each layer therein including at least one selected from the above materials.

The interlayer insulating layer 105 may cover the first gate electrode GE1, the second gate electrode GE2, and the third gate electrode GE3. The interlayer insulating layer 105 may include an inorganic insulating material such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂), and have a single layer or a multi-layered structure, each layer therein including at least one selected from the above materials.

The gate insulating layer 103 and the interlayer insulating layer 105 may include contact holes overlapping a source region and a drain region of each of the first active layer ACT1, the second active layer ACT2, and the third active layer ACT3. The first source electrode SE1 may be disposed on the interlayer insulating layer 105 to overlap the source region of the first active layer ACT1 and be connected to the first active layer ACT1 through a contact hole. The first drain electrode DE1 may be disposed on the interlayer insulating layer 105 to overlap the drain region of the first active layer ACT1 and be connected to the first active layer ACT1 through a contact hole. The second source electrode SE2 may be disposed on the interlayer insulating layer 105 to overlap the source region of the second active layer ACT2 and be connected to the second active layer ACT2 through a contact hole. The second drain electrode DE2 may be disposed on the interlayer insulating layer 105 to overlap the drain region of the second active layer ACT2 and be connected to the second active layer ACT2 through a contact hole. The third source electrode SE3 may be disposed on the interlayer insulating layer 105 to overlap the source region of the third active layer ACT3 and be connected to the third active layer ACT3 through a contact hole. The third drain electrode DE3 may be disposed on the interlayer insulating layer 105 to overlap the drain region of the third active layer ACT3 and be connected to the third active layer ACT3 through a contact hole.

Various configurations including an initialization voltage line Vint, a common voltage line ELVSS, a scan driver SCD, an emission driver EMD, or the like may be arranged in the side area SA. In an embodiment, the scan driver SCD and the emission driver EMD may also include a thin-film transistor, and the structure of the thin-film transistor may be similar to that of the first thin-film transistor TFT1, the second thin-film transistor TFT2, or the third thin-film transistor TFT3. The initialization voltage line Vint and the common voltage line ELVSS may be disposed on the interlayer insulating layer 105. In an embodiment, the initialization voltage line Vint, the common voltage line ELVSS, the first source electrode SE1, the first drain electrode DE1, the second source electrode SE2, the second drain electrode DE2, the third source electrode SE3, and the third drain electrode DE3 may be disposed in (or directly on) a same layer as each other and simultaneously formed through a same process.

A first organic insulating layer 107 may be disposed to cover the first source electrode SE1, the first drain electrode DE1, the second source electrode SE2, the second drain electrode DE2, the third source electrode SE3, and the third drain electrode DE3. The first organic insulating layer 107 may be entirely arranged in not only the display area DA but also the side area SA.

The first organic insulating layer 107 may include a general-purpose polymer such as benzocyclobutene, polyimide, hexamethyldisiloxane, polymethylmethacrylate or polystyrene, polymer derivatives having a phenol-based group, an acryl-based polymer, an imide-based polymer, an aryl ether-based polymer, an amide-based polymer, a fluorine-based polymer, a p-xylene-based polymer, or a vinyl alcohol-based polymer, and have a single layer or a multi-layered structure, each layer including at least one selected from the above materials.

The first organic insulating layer 107 may include contact holes respectively overlapping the first drain electrode DE1, the second drain electrode DE2, the third drain electrode DE3. A first conductive layer 108 may be disposed on the first organic insulating layer 107 and may include a first contact metal 1108, a second contact metal 2108, and a third contact metal 3108. The first contact metal 1108 may overlap the first drain electrode DE1 and be connected to the first drain electrode DE1 through a contact hole of the first organic insulating layer 107. The second contact metal 2108 may overlap the second drain electrode DE2 and be connected to the second drain electrode DE2 through a contact hole of the first organic insulating layer 107. The third contact metal 3108 may overlap the third drain electrode DE3 and be connected to the third drain electrode DE3 through a contact hole of the first organic insulating layer 107.

The first organic insulating layer 107 may include an opening overlapping the initialization voltage line Vint, and a portion of the first conductive layer 108 may be disposed in the opening of the first organic insulating layer 107 and connected to the initialization voltage line Vint by being in direct contact with the initialization voltage line Vint.

The first organic insulating layer 107 may include an opening overlapping the common voltage line ELVSS, and a portion of the first conductive layer 108 may be disposed in the opening of the first organic insulating layer 107 and connected to the common voltage line ELVSS by being in direct contact with the common voltage line ELVSS.

A second organic insulating layer 109 may be disposed on the first organic insulating layer 107. The second organic insulating layer 109 may be entirely arranged in not only the display area DA but also the side area SA.

The second organic insulating layer 109 may include a general-purpose polymer such as benzocyclobutene, polyimide, hexamethyldisiloxane, polymethylmethacrylate or polystyrene, polymer derivatives having a phenol-based group, an acryl-based polymer, an imide-based polymer, an aryl ether-based polymer, an amide-based polymer, a fluorine-based polymer, a p-xylene-based polymer, or a vinyl alcohol-based polymer, and have a single layer or a multi-layered structure, each layer therein including at least one selected from the above materials.

The second organic insulating layer 109 may include contact holes respectively overlapping the first contact metal 1108, the second contact metal 2108, and the third contact metal 3108. A second conductive layer 110 may be disposed on the second organic insulating layer 109 and may include a first sub-pixel electrode 1110, a second sub-pixel electrode 2110, and a third sub-pixel electrode 3110. The first sub-pixel electrode 1110 may overlap the first contact metal 1108 and be connected to the first drain electrode DE1 through the first contact metal 1108. The second sub-pixel electrode 2110 may overlap the second contact metal 2108 and be connected to the second drain electrode DE2 through the second contact metal 2108. The third sub-pixel electrode 3110 may overlap the third contact metal 3108 and be connected to the third drain electrode DE3 through the third contact metal 3108.

The second organic insulating layer 109 may include an opening overlapping the common voltage line ELVSS, and a portion of the second conductive layer 110 may be disposed in the opening of the first organic insulating layer 107 to be in direct contact with a portion of the first conductive layer 108, and furthermore be connected to the common voltage line ELVSS.

A pixel-defining layer 111 may be disposed on the second organic insulating layer 109. The pixel-defining layer 111 may be provided with openings respectively exposing the central portions of the first sub-pixel electrode 1110, the second sub-pixel electrode 2110, and the third sub-pixel electrode 3110. In other words, the pixel-defining layer 111 may cover an edge area (or an edge) of each of the first sub-pixel electrode 1110, the second sub-pixel electrode 2110, and the third sub-pixel electrode 3110. The openings of the pixel-defining layer 111 may respectively define emission areas of the light-emitting diodes (e.g., the first light-emitting diode LED1, the second light-emitting diode LED2, and the third light-emitting diode LED3).

An emission layer 112 may be disposed on the pixel-defining layer 111. The emission layer 112 may include a first emission portion 1112 overlapping the first sub-pixel electrode 1110, a second emission portion 2112 overlapping the second sub-pixel electrode 2110, and a third emission portion 3112 overlapping the third sub-pixel electrode 3110. The first emission portion 1112 may be disposed in the opening of the pixel-defining layer 111 corresponding to the first sub-pixel electrode 1110. The second emission portion 2112 may be disposed in the opening of the pixel-defining layer 111 corresponding to the second sub-pixel electrode 2110. The third emission portion 3112 may be disposed in the opening of the pixel-defining layer 111 corresponding to the third sub-pixel electrode 3110. The emission layer 112 may include a material that emits light of a preset color when a voltage is applied thereto. The emission layer 112 may include an emissive organic or inorganic material.

An opposite electrode 113 may be disposed on the pixel-defining layer 111. A portion of the opposite electrode 113 may be disposed in the opening of the pixel-defining layer 111 and be in direct contact with the first emission portion 1112. A portion of the opposite electrode 113 may be disposed in the opening of the pixel-defining layer 111 and be in direct contact with the second emission portion 2112. A portion of the opposite electrode 113 may be disposed in the opening of the pixel-defining layer 111 and be in direct contact with the third emission portion 3112.

The opposite electrode 113 may extend to not only the display area DA but also the side area SA. In an embodiment, for example, the opposite electrode 113 may extend to the side area SA and be in direct contact with a portion of the second conductive layer 110 in a region overlapping the common voltage line ELVSS. In such an embodiment, the opposite electrode 113 may be electrically connected to the second conductive layer 110, the first conductive layer 108, and the common voltage line ELVSS.

The first light-emitting diode LED1 may include the first sub-pixel electrode 1110, the first emission portion 1112, and the opposite electrode 113 described above. The second light-emitting diode LED2 may include the second sub-pixel electrode 2110, the second emission portion 2112, and the opposite electrode 113 described above. The third light-emitting diode LED3 may include the third sub-pixel electrode 3110, the third emission portion 3112, and the opposite electrode 113 described above. Because the opposite electrode 113 may be entirely integrally formed as a single unitary indivisible part, the opposite electrode 113 may be understood as a portion of the light-emitting diode at the portion overlapping the sub-pixel electrode of each light-emitting diode.

A first dam DM1 and a second dam DM2 may be arranged in the side area SA. In an embodiment, the first dam DM1 may overlap the common voltage line ELVSS, and the second dam DM2 may be located in the +x direction of the common voltage line ELVSS. The first dam DM1 and the second dam DM2 may be configured to prevent the organic encapsulation layer 117 from overflowing beyond the edge of the display substrate 3.

The first dam DM1 may include a portion of the second organic insulating layer 109. In an embodiment, for example, the first dam DM1 may include a first dam portion 109-1 of the second organic insulating layer 109. The first dam portion 109-1 of the second organic insulating layer 109 may be disposed on the common voltage line ELVSS. The first dam DM1 may include a portion of the pixel-defining layer 111. In an embodiment, for example, the first dam DM1 may include a first dam portion 111-1 of the pixel-defining layer 111. The first dam portion 111-1 of the pixel-defining layer 111 may be disposed on the first dam portion 109-1 of the second organic insulating layer 109. The first dam DM1 may further include a first spacer SPC-1 disposed on the first dam portion 111-1 of the pixel-defining layer 111.

The second dam DM2 may include a portion of the first organic insulating layer 107. In an embodiment, for example, the second dam DM2 may include a second dam portion 107-2 of the first organic insulating layer 107. The second dam portion 107-2 of the second organic insulating layer 107 may be disposed on the interlayer insulating layer 105. The second dam DM2 may include a portion of the second organic insulating layer 109. In an embodiment, for example, the second dam DM2 may include a second dam portion 109-2 of the second organic insulating layer 109. The second dam portion 109-2 of the second organic insulating layer 109 may be disposed on the second dam portion 107-2 of the first organic insulating layer 107. The second dam DM2 may include a portion of the pixel-defining layer 111. In an embodiment, for example, the second dam DM2 may include a second dam portion 111-2 of the pixel-defining layer 111. The second dam portion 111-2 of the pixel-defining layer 111 may be disposed on the second dam portion 109-2 of the second organic insulating layer 109. The second dam DM2 may further include a second spacer SPC-2 disposed on the second dam portion 111-2 of the pixel-defining layer 111.

The thin-film encapsulation layer TFE may be disposed on the display element layer DISL to entirely cover the display element layer DISL. The thin-film encapsulation layer TFE may include at least one inorganic encapsulation layer and at least one organic encapsulation layer. In an embodiment, for example, the thin-film encapsulation layer TFE may include a first inorganic encapsulation layer 115, an organic encapsulation layer 117, and a second inorganic encapsulation layer 119. The first inorganic encapsulation layer 115 may be disposed on the display element layer DISL and be entirely integrally formed over the display area DA and the side area SA. The organic encapsulation layer 117 may be disposed on the first inorganic encapsulation layer 115. A portion of the organic encapsulation layer 117 may be arranged in the display area DA and the side area SA, and a portion of the organic encapsulation layer 117 may be blocked by the first dam DM1 or the second dam DM2 and thus may not be arranged beyond the first dam DM1 or the second dam DM2. The second inorganic encapsulation layer 119 may be disposed on the organic encapsulation layer 117 and be entirely integrally formed over the display area DA and the side area SA.

The first inorganic encapsulation layer 115 and the second inorganic encapsulation layer 119 may include at least one inorganic insulating material selected from silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The organic encapsulation layer 117 may include a polymer-based material. The polymer-based material may include at least one selected from a silicon-base resin, an acryl-based resin, an epoxy-based resin, polyimide, and polyethylene.

The input-sensing layer 20 may include at least one insulating layer and at least one conductive layer. In an embodiment, for example, the input-sensing layer 20 may include a first touch conductive layer 201, a first touch insulating layer 202, a second touch conductive layer 203, and a second touch insulating layer 204. The first touch conductive layer 201 may be disposed on the second inorganic encapsulation layer 119 and may include a plurality of electrodes. In another embodiment, an additional insulating layer may be disposed between the first touch conductive layer 201 and the second inorganic encapsulation layer 119. The first touch insulating layer 202 may be disposed to cover the first touch conductive layer 201. In an embodiment, the first touch insulating layer 202 may be a planarization layer. The second touch conductive layer 203 may be disposed on the first touch insulating layer 202 and may include a plurality of electrodes. In an embodiment, some of the electrodes of the second touch conductive layer 203 may be electrically connected to some of the electrodes of the first touch conductive layer 201 through a contact hole defined or formed in the first touch insulating layer 202. The second touch insulating layer 204 may be disposed to cover the second touch conductive layer 203. In an embodiment, the second touch insulating layer 204 may be a planarization layer.

The second protrusion PR2 may be disposed on the input-sensing layer 20, for example, the upper surface of the second touch insulating layer 204. The second protrusion PR2 may be disposed in the second protrusion area PRA2. The second protrusion area PRA2 may be an area in which an organic layer is not arranged. In an embodiment, for example, the second protrusion area PR2 may be an area in which the organic encapsulation layer 117, the first organic insulating layer 107, the second organic insulating layer 109, and the like are not arranged. In an embodiment, the second protrusion area PRA2 may be an area between an edge in the +x direction of the second dam DM2 and an edge in the +x direction of the buffer layer 101. In an embodiment, the length in the x axis direction of the second protrusion area PRA2 may be about 200 μm.

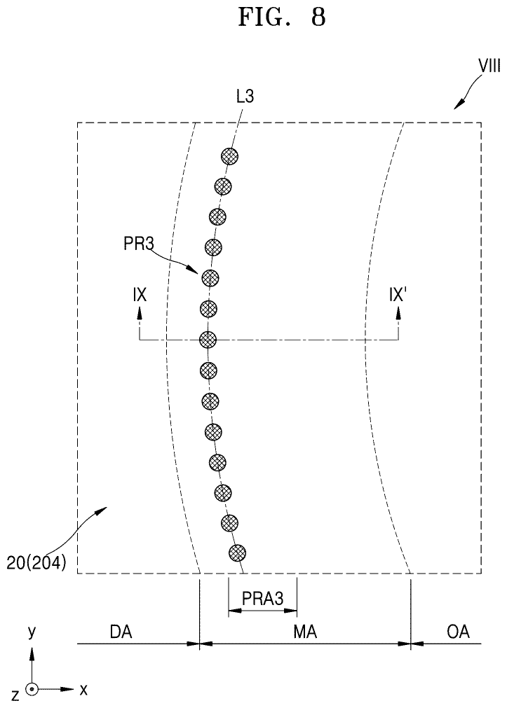

FIG. 8 is an enlarged plan view of a portion of the display substrate 3 according to an embodiment, and an enlarged plan view of a region VIII of FIG. 3.

In FIG. 8, the intermediate area MA of the display substrate 3 (see FIG. 3) is enlargedly shown. A plurality of third protrusions PR3 may be arranged in the intermediate area MA. In an embodiment, the third protrusions PR3 may be circular in a plan view. The disclosure is not limited to the shape of the third protrusions PR3, and the shape of the third protrusions PR3 may be variously modified as described below.

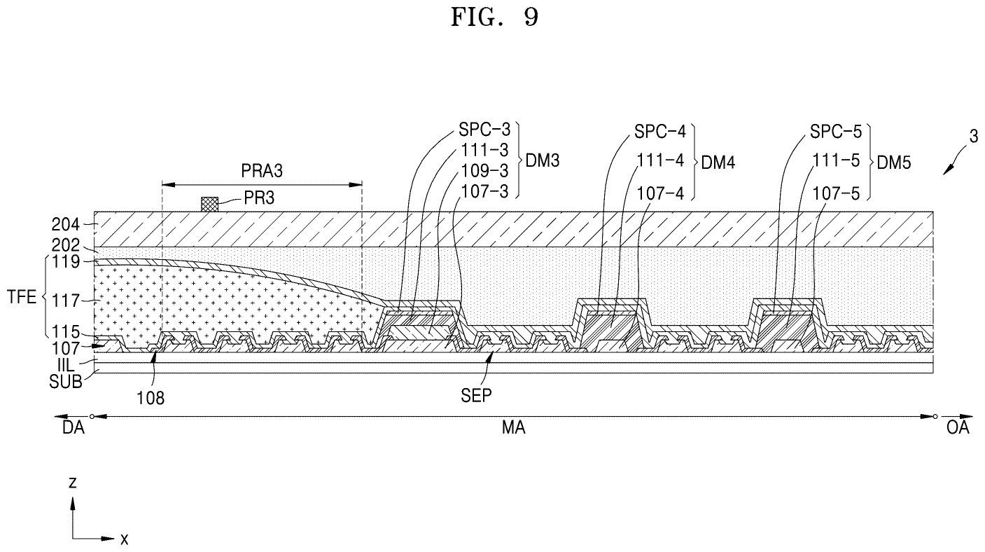

In an embodiment, the third protrusions PR3 may be arranged along an imaginary line, for example, a third line L3. In an embodiment, for example, the center of the third protrusion PR3 may be located on the third line L3. In an embodiment, the third line L3 may be a curved line extending in a direction in which the intermediate area MA extends. The third protrusions PR3 may be arranged between the boundary of the display area DA and the intermediate area MA, and the boundary between the intermediate area MA and the opening area OA. In an embodiment, the third protrusions PR3 may be arranged in a preset area inside the intermediate area MA, for example, arranged within a third protrusion area PRA3. The third protrusion area PRA3 will be described in greater detail with reference to FIG. 9. Although only one third line L3 is shown in FIG. 8, the disclosure is not limited thereto, and there may be a plurality of imaginary lines on which the third protrusions PR3 are arranged.

The third protrusions PR3 may be disposed on the input-sensing layer 20. In an embodiment, for example, the input-sensing layer 20 may include the second touch insulating layer 204, and the third protrusions PR3 may be disposed on the second touch insulating layer 204.

FIG. 9 is a cross-sectional view of a portion of the display substrate 3 according to an embodiment and is a cross-sectional view of the display substrate, taken along line IX-IX′ of FIG. 8.

Referring to FIG. 9, a plurality of separators SEP may be arranged in the intermediate area MA. The separators SEP may be disposed on an inorganic insulating layer IIL. The inorganic insulating layer IIL may include the buffer layer 101, the gate insulating layer 103, and the interlayer insulating layer 105. The separators SEP may disconnect a specific layer in the intermediate area MA. Each separator SEP may include a portion included in the first organic insulating layer 107 and a portion included in the first conductive layer 108.

A third dam DM3, a fourth dam DM4, and a fifth dam DM5 may be arranged in the intermediate area MA. The third dam DM3, the fourth dam DM4, and the fifth dam DM5 may be disposed on the inorganic insulating layer IIL. The third dam DM3, the fourth dam DM4, and the fifth dam DM5 may be sequentially arranged in a direction from the display area DA to the opening area OA (e.g., the +x direction in FIG. 9). The third dam DM3, the fourth dam DM4, and the fifth dam DM5 may prevent the organic encapsulation layer 117 from overflowing in a direction toward the opening area OA.

The third dam DM3 may include a portion of the first organic insulating layer 107. In an embodiment, for example, the third dam DM3 may include a third dam portion 107-3 of the first organic insulating layer 107. The third dam portion 107-3 of the first organic insulating layer 107 may be disposed on the inorganic insulating layer IIL. The third dam DM3 may include a portion of the second organic insulating layer 109. In an embodiment, for example, the third dam DM3 may include a third dam portion 109-3 of the second organic insulating layer 109. The third dam portion 109-3 of the second organic insulating layer 109 may be disposed on the third dam portion 107-3 of the first organic insulating layer 107. The third dam DM3 may include a portion of the pixel-defining layer 111. In an embodiment, for example, the third dam DM3 may include a third dam portion 111-3 of the pixel-defining layer 111. The third dam portion 111-3 of the pixel-defining layer 111 may be disposed on the third dam portion 109-3 of the second organic insulating layer 109. The third dam DM3 may include a third spacer SPC-3 disposed on the third dam portion 111-3 of the pixel-defining layer 111.

The fourth dam DM4 may include a portion of the first organic insulating layer 107. In an embodiment, for example, the fourth dam DM4 may include a fourth dam portion 107-4 of the first organic insulating layer 107. The fourth dam portion 107-4 of the first organic insulating layer 107 may be disposed on the inorganic insulating layer IIL. The fourth dam DM4 may include a portion of the pixel-defining layer 111. In an embodiment, for example, the fourth dam DM4 may include a fourth dam portion 111-4 of the pixel-defining layer 111. The fourth dam portion 111-4 of the pixel-defining layer 111 may be disposed on the fourth dam portion 107-4 of the first organic insulating layer 107. The fourth dam DM4 may include a fourth spacer SPC-4 disposed on the fourth dam portion 111-4 of the pixel-defining layer 111.

The fifth dam DM5 may include a portion of the first organic insulating layer 107. In an embodiment, for example, the fifth dam DM5 may include a fifth dam portion 107-5 of the first organic insulating layer 107. The fifth dam portion 107-5 of the first organic insulating layer 107 may be disposed on the inorganic insulating layer IIL. The fifth dam DM5 may include a portion of the pixel-defining layer 111. In an embodiment, for example, the fifth dam DM5 may include a fifth dam portion 111-5 of the pixel-defining layer 111. The fifth dam portion 111-5 of the pixel-defining layer 111 may be disposed on the fifth dam portion 107-5 of the first organic insulating layer 107. The fifth dam DM5 may include a fifth spacer SPC-5 disposed on the fifth dam portion 111-5 of the pixel-defining layer 111.

The first inorganic encapsulation layer 115 and the second inorganic encapsulation layer 119 of the thin-film encapsulation layer TFE may be entirely integrally or commonly arranged in the intermediate area MA. The first inorganic encapsulation layer 115 may cover the separators SEP, the third dam DM3, the fourth dam DM4, and the fifth dam DM5. The organic encapsulation layer 117 may be arranged in the display area DA and a portion of the intermediate area MA. In an embodiment, for example, the organic encapsulation layer 117 may be arranged in a direction to the display area DA (e.g., the −x direction in FIG. 9) with respect to the third dam DM3. The organic encapsulation layer 117 may be blocked by the third dam DM3 and thus may not be arranged beyond the third dam DM3. In another embodiment, a portion of the organic encapsulation layer 117 may be arranged beyond the third dam DM3 and be blocked by the fourth dam DM4 and thus may not be arranged beyond the fourth dam DM4. In another embodiment, a portion of the organic encapsulation layer 117 may be arranged beyond the third dam DM3 and the fourth dam DM4 and be blocked by the fifth dam DM5 and thus may not be arranged beyond the fifth dam DM5.

The first touch insulating layer 202 and the second touch insulating layer 204 may be sequentially disposed on the thin-film encapsulation layer TFE. Similar to FIG. 7, the first touch insulating layer 202 and the second touch insulating layer 204 may be planarization layers. Although FIG. 9 shows an embodiment where the first touch conductive layer 201 (see FIG. 7) and the second touch conductive layer 203 (see FIG. 7) are not arranged, for convenience of description, but the disclosure is not necessarily limited thereto. In another embodiment, a portion of the first touch conductive layer 201 (see FIG. 7) and the second touch conductive layer 203 (see FIG. 7) may be arranged in the intermediate area MA.

The third protrusion PR3 may be disposed on the upper surface of the second touch insulating layer 204. The third protrusion PR3 may be arranged in the third protrusion area PRA3.

The third protrusion are PRA3 may be located in a direction toward the display area DA (e.g., the −x direction) with respect to the first dam DM1. for convenience of description example, four separators SEP may be arranged in the direction to the display area DA (e.g., the −x direction) with respect to the first dam DM1. In an embodiment, an area between the edge of the separator SEP closest to the display area DA in a direction to the display area DA (e.g., the −x direction) and the edge of the separator SEP closest to the first dam DM1 in a direction to the first dam DM1 (e.g., the +x direction) may be defined as the third protrusion area PRA3. In an embodiment, the length in the x axis direction of the third protrusion area PRA3 may be about 200 micrometers (μm).

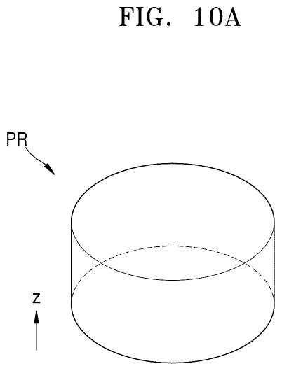

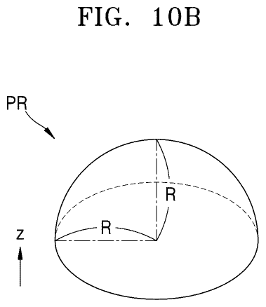

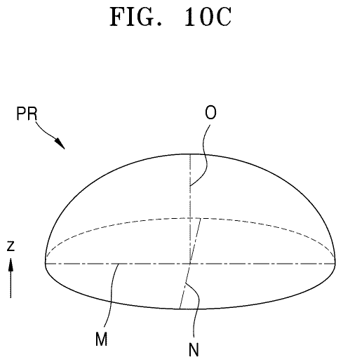

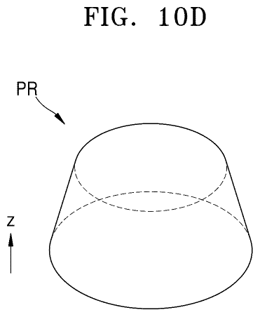

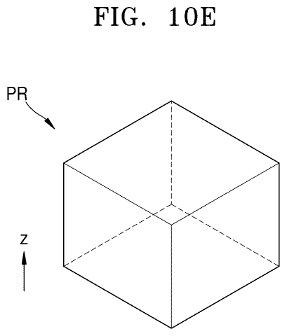

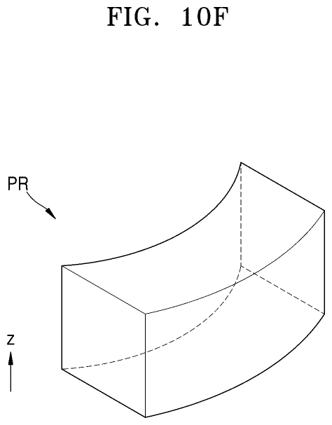

FIGS. 10A, 10B, 10C, 10D, 10E, and 10F are perspective views of protrusions according to various embodiments.

Each of the protrusions PR described below with reference to FIGS. 10A to 10F may correspond to the first protrusion PR1 of FIG. 5, the second protrusion PR2 of FIGS. 6 and 7, or the third protrusion PR3 of FIGS. 8 and 9. In other words, the first protrusion PR1, the second protrusion PR2, and the third protrusion PR3 may all be referred to as protrusions PR and may have one of the structures shown in FIGS. 10A to 10F.

Referring to FIG. 10A, in an embodiment, the protrusion PR may have a cylindrical structure. In such an embodiment, a diameter of the upper surface and a diameter of the lower surface of the protrusion PR may be equal to each other.

Referring to FIG. 10B, in another embodiment, the protrusion PR may have a half-spherical structure. In such an embodiment, the radius R of the protrusion PR may be constant.

Referring to FIG. 10C, in another embodiment, the protrusion PR may have a half-spheroid structure. In such an embodiment, the protrusion PR may have a major radius M, a minor radius N, and a height O.

Referring to FIG. 10D, in another embodiment, the protrusion PR may have a cylindrical structure. In such an embodiment, a diameter of the upper surface of the protrusion PR may be less than a diameter of the lower surface. In another embodiment, a diameter of the upper surface of the protrusion PR may be greater than a diameter of the lower surface.

Referring to FIG. 10E, in another embodiment, the protrusion PR may have a hexahedral structure. In an embodiment, for example, the protrusion PR may be a cube in which each edge has a same length, or may be a rectangular parallelepiped in which each edge has a different length.

Referring to FIG. 10F, in another embodiment, the protrusion PR may have a pillar structure with a bottom surface having a substantially arc shape. In such an embodiment, the protrusion PR may be three-dimensional, with the bottom surface corresponding to the shape of a portion of an arc with preset curvature and a width, and extending in one direction (for example, a +z direction). The curvature of the arc may be adjusted to correspond to the curvature of an area in which the protrusion PR is arranged, for example, the corner area CNA or the intermediate area MA.

In an embodiment, the first protrusion PR1, the second protrusion PR2, and the third protrusion PR3 inside a display substrate 3 may not have the structure of a same shape as each other. In an embodiment, for example, the first protrusion PR1 may have the cylindrical structure of FIG. 10A, the second protrusion PR2 may have the half-spherical structure of FIG. 10B, and the third protrusion PR3 may have the hexahedral structure of FIG. 10E.

In an embodiment, the first protrusion PR1, the second protrusion PR2, and the third protrusion PR3 in a display substrate 3 may not have the structure of a same size as each other. In an embodiment, for example, the first protrusion PR1, the second protrusion PR2, and the third protrusion PR3 all may have a hemispherical structure shown in FIG. 10B, but radii of the first protrusion PR1, the second protrusion PR2, and the third protrusion PR3 may be different from each other.

The shape and size of the protrusion PR may be selectively determined or changed depending on the characteristics of the surface on which the protrusion PR is to be disposed. In an embodiment, forming the protrusion PR may include disposing resin on the surface in a preset pattern and curing the disposed resin. In such an embodiment, the resin forming the protrusion PR may form a contact angle with the surface in a range of about 60° to about 100°, or may form a contact angle in a range of about 5° to about 50°. In other words, an angle between the protrusions PR and the surface (e.g., the upper surface of the input-sensing layer 20) on which the protrusions PR are disposed may be in a range of about 60° to about 100°, or may be in a range of about 5° to about 50°. In an embodiment, a planar area of the protrusion PR, that is, an area viewed from the +z direction may be tens to hundreds of square micrometers (μm²). In an embodiment, the height of the protrusion PR, that is, the z-axis length, may be about 300 micrometers (μm) or less.

The shapes of the protrusion PR in various embodiments have been described with reference to the drawings, but these are merely examples. The protrusions PR of the disclosure are not necessarily limited to these shapes, dimensions, and orientations. It would be understood that, as long as the protrusions PR are disposed to be apart from each other on the preset surface and may have a structure protruding from the surface, the protrusions PR fall within the scope of the disclosure regardless of the shape of the protrusions PR.

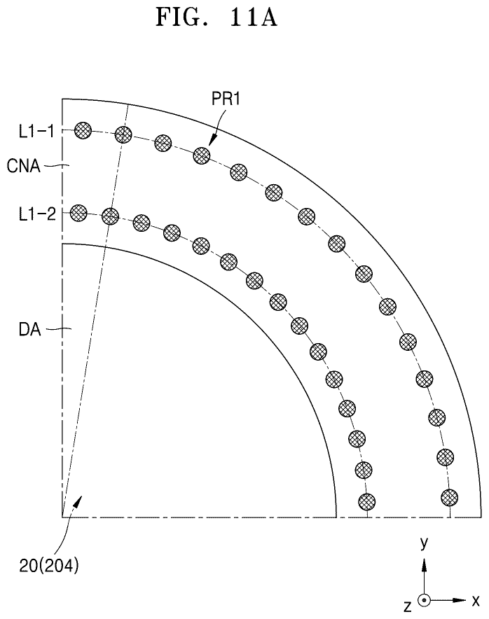

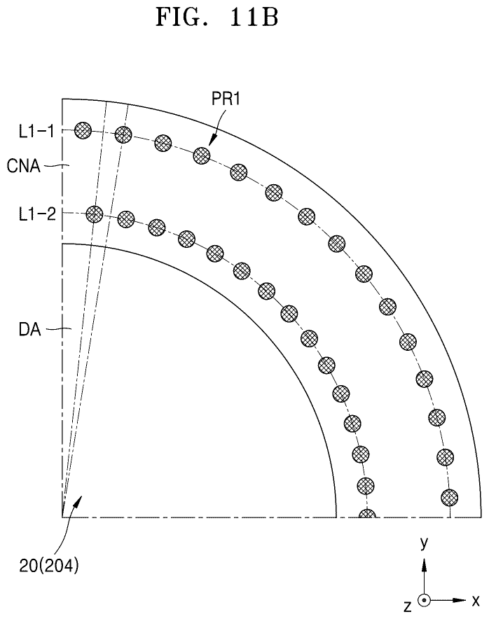

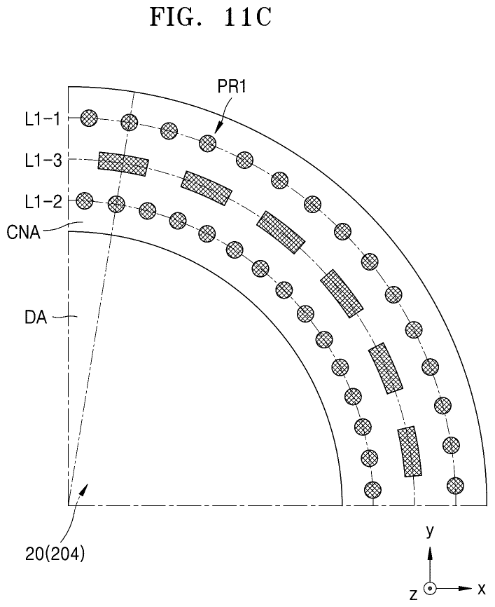

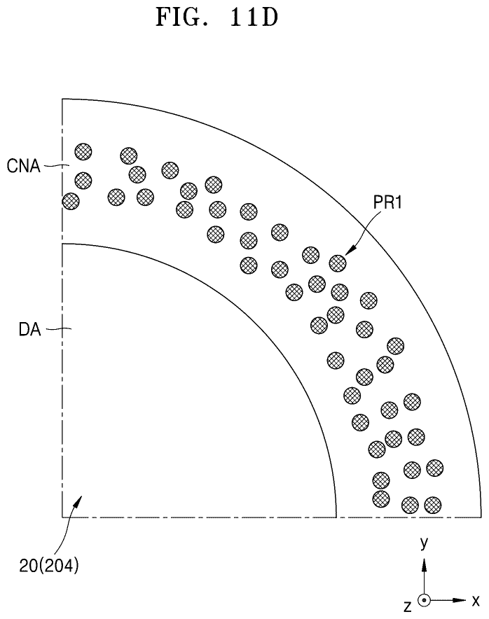

FIGS. 11A, 11B, 11C, and 11D are plan views showing various embodiments in which the protrusions may be arranged in a corner region.

Hereinafter, for convenience of description, the corner area CNA and the configuration or arrangement of the first protrusions PR1 therein, and it would be understood that the configuration or arrangement of the first protrusions PR1 described below is similarly applicable to the side area SA and the second protrusions PR2 in FIG. 6 and the intermediate area MA and the third protrusions PR3 in FIG. 8.

Referring to FIG. 11A, the first protrusions PR1 may be arranged along a plurality of lines. In an embodiment, for example, the first protrusions PR1 may be arranged along two imaginary lines of a first first line (hereinafter, will be referred to as “first-1 line”) L1-1 and a second first line ((hereinafter, will be referred to as “first-2 line”) L1-2 extending along the curve of the corner area CNA. In such an embodiment, the center of each of the first protrusions PR may be located on the first-1 line L1-1 or the first-2 line L1-2. The first-1 line L1-1 may be arranged outside the first-2 line L1-2. That is, the first-2 line L1-2 may be closer to the display area DA than the first-1 line L1-1.

In an embodiment, the first protrusion PR1 on the first-1 line L1-1 and the first protrusion PR1 on the first-2 line L1-2 may be aligned to each other. In such an embodiment, an imaginary line (expressed as a dashed line) along the radius of the curve of the corner area CNA may simultaneously pass through the first protrusion PR1 on the first-1 line L1-1 and the first protrusion PR1 on the first-2 line L1-2. In other words, the centers of the first protrusion PR1 on the first-1 line L1-1 and the first protrusion PR1 on the first-2 line L1-2 may be located on the same dashed line.

Referring to FIG. 11B, in another embodiment, the first protrusions PR1 may be arranged along the plurality of imaginary lines, that is, the first-1 line L1-1 and the first-2 line L1-2, as described above with reference to FIG. 11A.

In an embodiment, the first protrusion PR1 on the first-1 line L1-1 and the first protrusion PR1 on the first-2 line L1-2 may cross each other. In such an embodiment, an imaginary line (expressed as a dashed line) along the radius of the curve of the corner area CNA may not simultaneously pass through the first protrusion PR1 on the first-1 line L1-1 and the first protrusion PR1 on the first-2 line L1-2. When drawing the dashed line along the radius of the curve of the corner area CNA to pass through the first protrusion PR1 on the first-1 line L1-1 and the dashed line along the radius of the curve of the corner area CNA to pass through the first protrusion PR1 on the first-2 line L1-2, the two dashed lines do not overlap each other. In other words, the first protrusions PR1 may be alternately arranged on the first-1 line L1-1 and the first-2 line L1-2 along the curvature direction of the corner area CNA.

Referring to FIG. 11C, in another embodiment, the first protrusions PR1 may be arranged along three imaginary lines. The first protrusions PR1 may be arranged along three imaginary lines of the first-1 line L1-1, the first-2 line L1-2, and a third first line (hereinafter, will be referred to as “first-3 line”) L1-3. The first-1 line L1-1 and the first-2 line L1-2 in FIG. 11C are similar to those described with reference to FIGS. 11A and 11B.

The first-3 line L1-3 may extend in a same direction as the first-1 line L1-1 and the first-2 line L1-2, that is, the curvature direction of the corner area CNA. The first-3 line L1-3 may be arranged between the first-1 line L1-1 and the first-2 line L1-2. The first protrusions PR1 arranged on the first-3 line L1-3 may be different in shape from the first protrusions PR1 arranged on the first-1 line L1-1 or the first-2 line L1-2. In an embodiment, the first protrusions PR1 arranged on the first-1 line L1-1 or the first-2 line L1-2 may have a circular shape in a plan view. In an embodiment, for example, the first protrusions PR1 arranged on the first-1 line L1-1 or the first-2 line L1-2 may have the cylindrical shape of FIG. 10A or a half-spherical shape of FIG. 10B. In an embodiment, the first protrusions PR1 arranged on the first-3 line L1-3 may have an arc shape in a plan view. In an embodiment, for example, the first protrusions PR1 arranged on the first-3 line L1-3 may have an arc shape of FIG. 10F.

However, the disclosure is not limited to the specific shape of the first protrusions PR1. It would be understood that the first protrusions PR1 may be arranged along a plurality of paths (lines), and the first protrusions PR1 arranged on each path (line) may be different in shape in the embodiments shown in FIGS. 11A to 11C.

Referring to FIG. 11D, the first protrusions PR1 may be arranged randomly without following a specific path or a predetermined arrangement. In an embodiment, the first protrusions PR1 may be apart from each other. In an embodiment, a distance between the first protrusions PR1 may not be constant. In an embodiment, the first protrusions PR1 may be different in shape or size. In an embodiment, the first protrusions PR1 may be arranged within the corner area CNA.

The configuration positions and relationships of the first protrusions PR1 in various embodiments are described above with reference to FIGS. 11A to 11D. However, the disclosure is not limited to the specific configuration position of the first protrusions PR1. The configuration positions of the first protrusions PR1 may accommodate process errors. In an embodiment, the process errors may be in a range about 40 μm to about 60 μm.

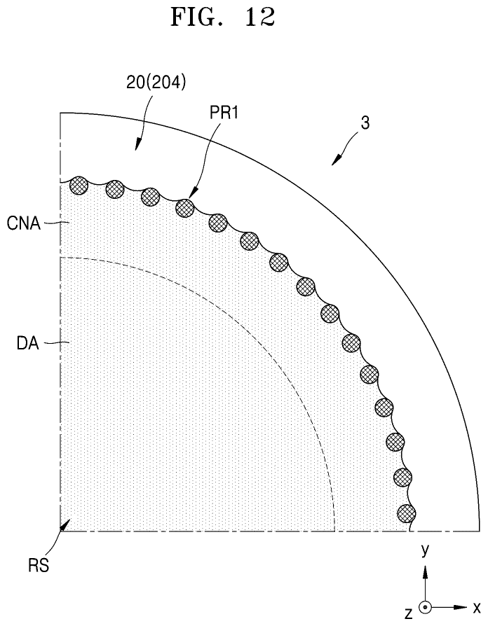

FIG. 12 is an enlarged plan view of a portion of a display substrate according to an embodiment and shows an embodiment in which resin RS is provided to the embodiment shown in FIG. 5.

Referring to FIG. 12, in an embodiment, the resin RS may be disposed on the display substrate 3. The resin RS may be disposed to correspond to an area to be covered. In an embodiment, for example, an area to be covered by the resin RS may be the display area DA and a portion of the corner area CNA.

As described below, the resin RS may be disposed on the display substrate 3 in a liquid state and then cured. When the resin RS is disposed on the display substrate 3 in a liquid state, the resin RS may flow on the display substrate 3. In this case, the resin RS may flow toward the edge of the display substrate 3, for example, toward the corner area CNA. When there is no structure for blocking flowing of the resin RS, the resin RS may overflow beyond the edge of the display substrate 3.

In an embodiment, the plurality of first protrusions PR1 may be configured to control the flowing of the resin RS in the corner area CNA. In such an embodiment, when the resin RS encounters the first protrusion PR1 while flowing, the resin RS will flow by bypassing the first protrusion PR1. In this case, when an interval between the first protrusions PR1 is sufficiently small, a capillary effect or lateral capillary force may occur between the first protrusions PR1 and the resin RS. Accordingly, the resin RS may be in contact with the first protrusions PR1 and may not move beyond the first protrusions PR1. In other words, the edge of the resin RS may be formed between the first protrusions PR1.

Although FIG. 12 shows an embodiment where the edge of the resin RS is approximately curved toward the display area DA, this is merely an example, and the scope of the disclosure is not limited thereto. The shape of the edge of the resin RS may be variously modified depending on the composition of the resin RS, the composition, surface condition and the like of the first protrusion PR1.

In an embodiment, as described above, the edge of the resin RS is formed between the first protrusions PR1, such that the edge of the resin RS may be maintained even when the resin RS is cured. casein a case where there is no first protrusion PR1, the resin RS may shrink when cured. In this case, it may occur that an area intended to be covered with resin RS may not be sufficiently or effectively covered. In an embodiment, where the first protrusions PR1 are arranged, the edge of the resin RS is taken between the first protrusions PR1, a force (e.g., capillary adhesive force) may occur that counteracts the shrinking force when the resin RS is cured. Accordingly, the resin RS may be fixed in an intended position without shrinking.

In such an embodiment, where the resin RS is disposed on the display substrate 3, the first protrusions PR1 may define the boundary (or the edge) of the resin RS and maintain the boundary while the resin RS is cured. Accordingly, the boundary of the region in which the resin RS is arranged may be precisely controlled through the first protrusions PR1. Due to the presence of the first protrusions PR1, the resin RS may be accurately disposed in a preset configuration area.

The surface tension of the constituent material of the first protrusions PR1 may be greater than the surface tension of the constituent material of the resin RS. In an embodiment, the constituent material of the resin RS may be the same as the constituent material of the first protrusions PR1. In an embodiment, for example, the first protrusions PR1 may be structures formed by disposing a same material as the resin RS and curing the material. In an embodiment, the constituent material of the resin RS may be different from the constituent material of the first protrusions PR1. In an embodiment, example, the first protrusions PR1 and the resin RS may include materials such as silicone polymer, polyurethane (PU), acryl, or the like, but composition ratios thereof in the third protrusions PR3 and the resin RS may be different from each other.

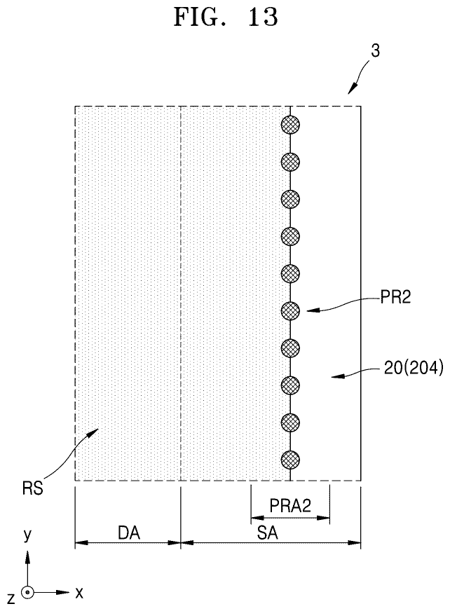

FIG. 13 is an enlarged plan view of a portion of the display substrate 3 according to an embodiment and shows an embodiment in which the resin RS is provided to the embodiment shown in FIG. 6.

The resin RS may be disposed on the display substrate 3. The resin RS may be disposed to correspond to an area to be covered. In an embodiment, for example, an area to be covered by the resin RS may be the display area DA and a portion of the side area SA.

As described above with reference to FIG. 12, a structure to control the flowing of the resin RS when the resin RS is disposed on the display substrate 3 in a liquid state may be desired.

The second protrusions PR2 may control the flowing of the resin RS in the side area SA. When the resin RS encounters the second protrusion PR2 while flowing, the resin RS will flow by bypassing the second protrusion PR2. In this case, when an interval between the second protrusions PR2 is sufficiently small, a capillary effect or lateral capillary force may occur between the second protrusions PR2 and the resin RS. Accordingly, the resin RS may be in contact with the second protrusions PR2 and may not move beyond the second protrusions PR2, and the edge of the resin RS may be formed between the second protrusions PR2.

Although FIG. 13 shows an embodiment where the edge of the resin RS is a straight line extending approximately in a y axis, this is merely an example, and the scope of the disclosure is not limited thereto. The shape of the edge of the resin RS may be variously modified depending on the composition of the resin RS, the composition, surface condition and the like of the first protrusion PR1.

In an embodiment, the edge of the resin RS is formed between the second protrusions PR2, such that the edge of the resin RS may be maintained even when the resin RS is cured. In a case where there is no second protrusion PR2, the resin RS may shrink when cured. In this case, it may occur that an area intended to be covered with resin RS may not be sufficiently or effectively covered. In an embodiment where the second protrusions PR2 are arranged, the edge of the resin RS is taken between the second protrusions PR2, a force (e.g., capillary adhesive force) may occur that counteracts the shrinking force when the resin RS is cured. Accordingly, the resin RS may be fixed in an intended position (e.g., within the second protrusion area PRA2) without shrinking.

In an embodiment, where the resin RS is disposed on the display substrate 3, the second protrusions PR2 may define the boundary (or the edge) of the resin RS and maintain the boundary while the resin RS is cured. Accordingly, the boundary of the region in which the resin RS is arranged may be precisely controlled through the second protrusions PR2. Due to the presence of the second protrusions PR2, the resin RS may be accurately disposed in a preset configuration area.

The surface tension of the constituent material of the second protrusions PR2 may be greater than the surface tension of the constituent material of the resin RS. In an embodiment, the constituent material of the resin RS may be the same as the constituent material of the second protrusions PR2. In an embodiment, for example, the second protrusions PR2 may be structures formed by disposing the same material as the resin RS and curing the material. In an embodiment, the constituent material of the resin RS may be different from the constituent material of the second protrusions PR2. In an embodiment, for example, the second protrusions PR2 and the resin RS may include materials such as silicone polymer, polyurethane (PU), acryl, and the like, but composition ratios thereof in the third protrusions PR3 and the resin RS may be different from each other.

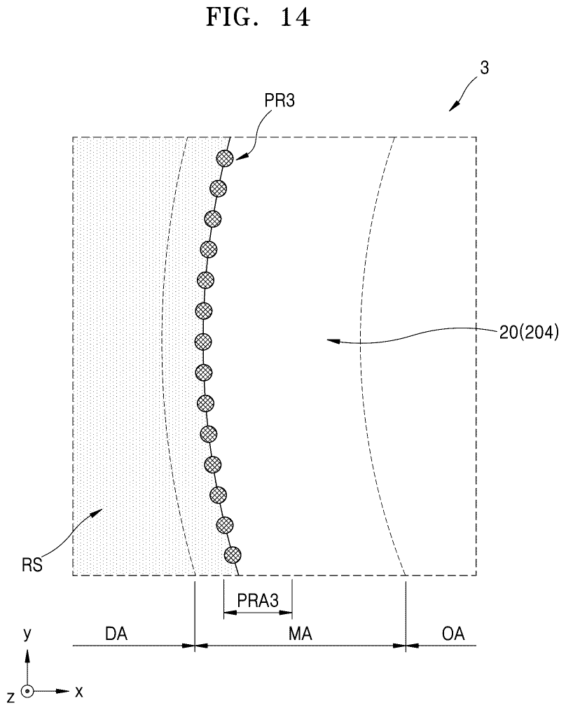

FIG. 14 is an enlarged plan view of a portion of the display substrate 3 according to an embodiment and shows an embodiment in which resin RS is provided to the embodiment shown in FIG. 8.

Referring to FIG. 14, the resin RS may be disposed on the display substrate 3. The resin RS may be disposed to correspond to an area to be covered. In an embodiment, example, an area to be covered by the resin RS may be the display area DA and a portion of the intermediate area MA.

As described above with reference to FIG. 12, a structure to control the flowing of the resin RS when the resin RS is disposed on the display substrate 3 in a liquid state may be desired. The third protrusions PR3 may control the flowing of the resin RS in the intermediate area MA. When the resin RS encounters the third protrusion PR3 while flowing, the resin RS will flow by bypassing the third protrusion PR3. In this case, when an interval between the third protrusions PR3 is sufficiently small, a capillary effect or lateral capillary force may occur between the third protrusions PR3 and the resin RS. Accordingly, the resin RS may be in contact with the third protrusions PR3 and may not move beyond the third protrusions PR3, and the edge of the resin RS may be formed between the third protrusions PR3.

Although FIG. 14 shows an embodiment where the edge of the resin RS is a line approximately in contact with the curve of the intermediate area MA, this is merely an example, and the scope of the disclosure is not limited thereto. The shape of the edge of the resin RS may be variously modified depending on the composition of the resin RS, the composition, surface condition and the like of the third protrusion PR3.

In an embodiment, the edge of the resin RS is formed between the third protrusions PR3, the edge of the resin RS may be maintained even when the resin RS is cured. In a case where there is no third protrusion PR3, the resin RS may shrink when cured. In this case, it may occur that an area intended to be covered with resin RS may not be sufficiently or effectively covered. In an embodiment where the third protrusions PR3 are arranged, the edge of the resin RS is taken between the third protrusions PR3, a force (e.g., capillary adhesive force) may occur that counteracts the shrinking force when the resin RS is cured. Accordingly, the resin RS may be fixed in an intended position (e.g., within the third protrusion area PRA3) without shrinking.

In an embodiment, where the resin RS is disposed on the display substrate 3, the third protrusions PR3 may define the boundary (or the edge) of the resin RS and maintain the boundary while the resin RS is cured. Accordingly, the boundary of the region in which the resin RS is arranged may be precisely controlled through the third protrusions PR3. Due to the presence of the third protrusions PR3, the resin RS may be accurately disposed in a preset configuration area.

The surface tension of the constituent material of the third protrusions PR3 may be greater than the surface tension of the constituent material of the resin RS. In an embodiment, the constituent material of the resin RS may be the same as the constituent material of the third protrusions PR3. In an embodiment, for example, the third protrusions PR3 may be structures formed by disposing the same material as the resin RS and curing the material. In an embodiment, the constituent material of the resin RS may be different from the constituent material of the second protrusions PR2. In an embodiment, for example, the third protrusions PR3 and the resin RS may include materials such as silicone polymer, polyurethane (PU), acryl, and the like, but composition ratios thereof in the third protrusions PR3 and the resin RS may be different from each other.

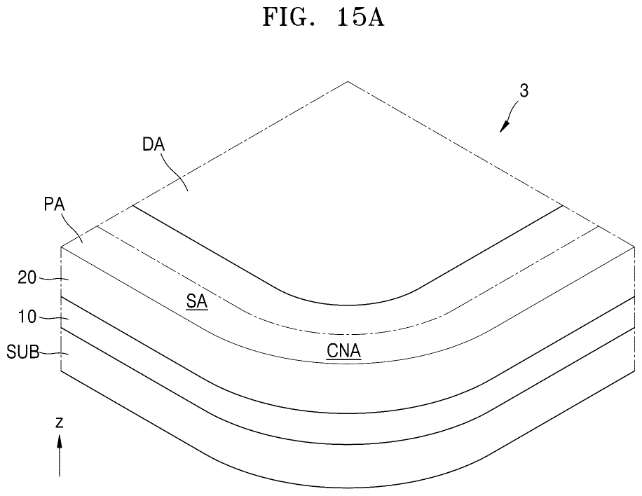

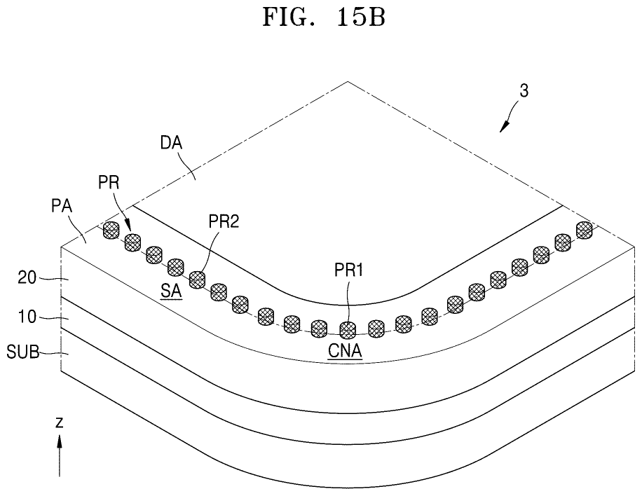

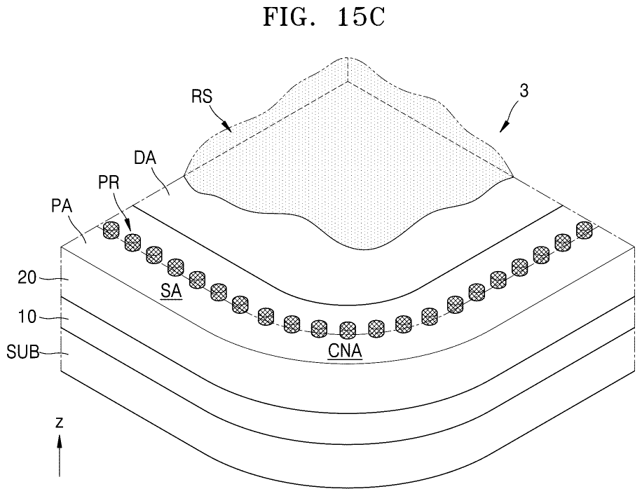

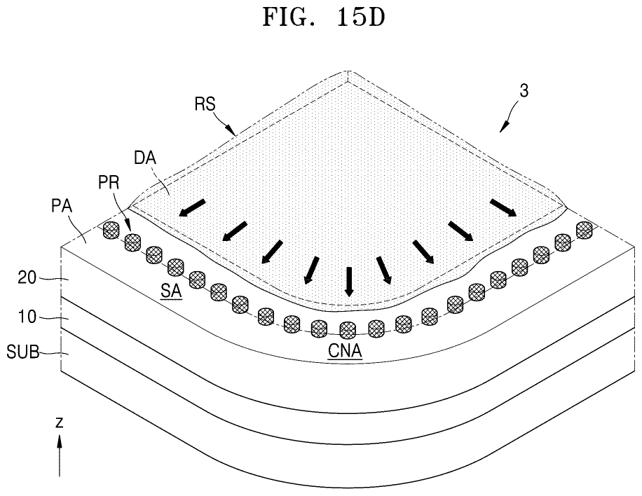

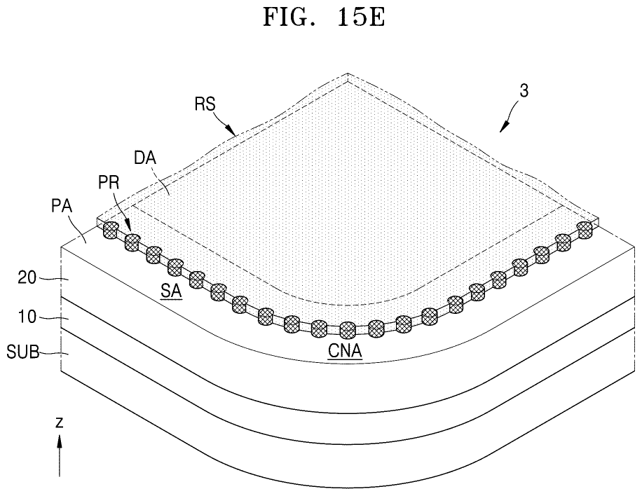

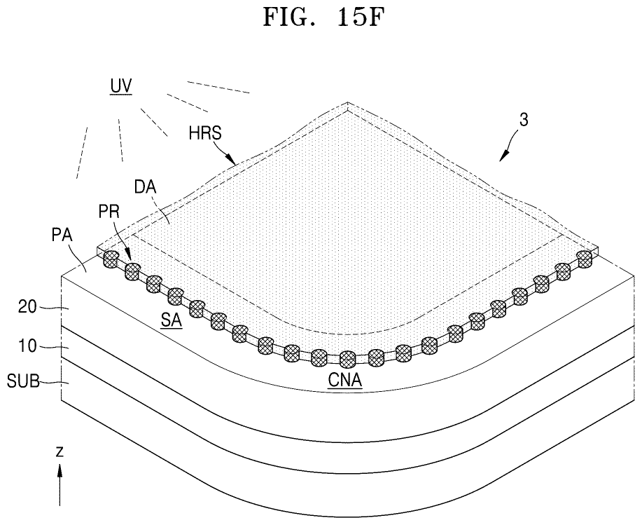

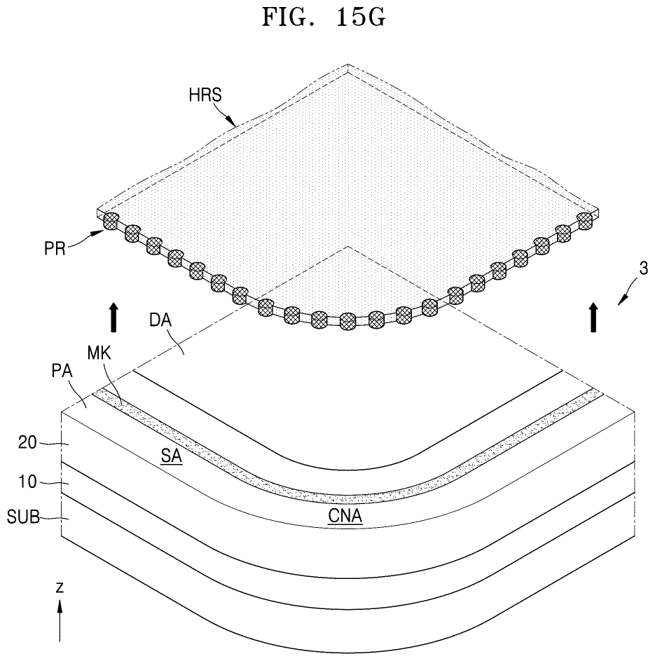

FIGS. 15A to 15G are schematic cross-sectional views showing operations corresponding to a process of manufacturing a display apparatus according to an embodiment.

Hereinafter, a process of forming a protective film on the display substrate 3 using the resin and completing the subsequent process, and then removing the protective film will be described with reference to FIGS. 15A to 15G. Hereinafter, a portion of the peripheral area PA of the display substrate 3 where the corner area CNA and a portion of the side area SA are located is enlargedly shown in FIGS. 15A to 15G and the portion of the peripheral area PA of the display substrate 3 will be mainly described. However, this is for convenience of illustration and description, and the disclosure is not necessarily limited thereto. It would be understood that the process described mainly for the corner area CNA is equally applicable to the side area SA (see FIG. 13) and the intermediate area MA (see FIG. 14).

Referring to FIG. 15A, the display substrate 3 including the substrate SUB, the image generating layer 10, and the input-sensing layer 20 may be prepared. The image generating layer 10 and the input-sensing layer 20 may be sequentially disposed on the substrate SUB. The display substrate 3 (or the substrate SUB) may include the display area DA and the peripheral area PA. The peripheral area PA may include the side area Sa corresponding to the lateral side of the display substrate 3 (or the substrate SUB), and the corner area CNA corresponding to the corner.

Referring to FIG. 15B, the protrusions PR may be provided (formed or disposed) on the input-sensing layer 20. The protrusions PR may be arranged in the side area SA and the corner area CNA. It would be understood that the protrusions PR arranged in the corner area CNA are the first protrusions PR1, and the protrusions PR arranged in the side area SA are the second protrusions PR2. Hereinafter, for convenience of description, these protrusions will be collectively referred to as the protrusions PR.

The protrusions PR may be arranged in a direction in which the side area SA and the corner area CNA extend. In other words, the protrusions PR may be arranged along the peripheral area PA. That is, the protrusions PR may be arranged approximately along the edge of the display substrate 3. Accordingly, the protrusions PR may form one boundary or fence located within the peripheral area PA.

Referring to FIG. 15C, the resin RS may be provided or disposed on the input-sensing layer 20. In such an operation, the resin RS may be in a liquid state. Accordingly, the resin RS may be amorphous. In an embodiment, the resin RS may be arranged within the display area DA. In another embodiment, the resin RS may be arranged over the display area DA and the peripheral area PA. In a current operation, the resin RS may be apart from the protrusions PR.

Referring to FIG. 15D, the resin RS may flow. In an embodiment, the resin RS may flow toward the peripheral area PA, that is, toward the edge of the display substrate 3. In an embodiment, the flowing of the resin RS may be caused by gravity. In another embodiment, the flowing of the resin RS may occur due to pressure, for example, pressure in the −z direction.

Referring to FIG. 15E, the resin RS may be in contact with the protrusions PR and stop flowing. In other words, the edge of the area in which the resin RS is arranged may be determined by the protrusions PR. In this case, the edge of the resin RS may be located between the protrusions PR as described above with reference to FIGS. 12 to 14.

Although FIG. 15E shows an embodiment where the thickness (or the length in a z axis direction) of the resin RS is substantially equal to the height (or the length in the z axis direction) of the protrusions PR, the disclosure is not necessarily limited thereto. In another embodiment, the thickness of the resin RS may be greater than the height of the protrusions PR. In such an embodiment, the resin RS may have a preset slope and be in contact with the protrusions PR. The slope angle of the resin RS may change depending on the kind of the material of the resin RS, the amount of disposed resin RS, and the like. In an embodiment, the slope angle of the resin RS may be in a range of about 1° and about 30°.

Referring to FIGS. 15E and 15F together, the resin RS may be cured. In an embodiment, a film HRS (or cured resin) may be formed by curing the resin RS. In an embodiment, an operation of curing the resin RS may include radiating an ultraviolet (UV) ray to the entire surface of the resin RS. In such an embodiment, the resin RS may include UV curable resin.

When the resin RS is cured to change into the film HRS, shrinking force may occur to the resin RS. When force that prevents the resin RS from shrinking is not provided, the resin RS may shrink, the edge of the film HRS may move toward the display area DA and may be finally located within the display area DA. The film HRS may protect the display substrate 3 during the subsequent process. Accordingly, in a case where the resin RS shrinks while cured and the edge of the film HRS moves, a portion of the surface of the display substrate 3, which is covered by the resin RS before the operation of curing but exposed through the resin RS after the operation of curing, may not be protected. This may finally lead to quality deterioration of the display apparatus.

The protrusions PR may effectively prevent such a phenomenon. As described above, the edge of the resin RS may be taken between the protrusions PR by a capillary effect or lateral capillary force. The force provided by the lateral capillary force may counteract the forces that cause the resin RS to shrink while the resin RS is cured. Accordingly, the resin RS may be cured while remaining in a position as shown in FIG. 15E. Accordingly, the shape of the film HRS (or the cured resin) shown in FIG. 15F is equal to the shape of the resin RS shown in FIG. 15E. The edge of the resin RS before cured may be equal to the edge of the film HRS after being cured. Accordingly, in an embodiment where the protrusions PR are provided, the resin RS may be cured while maintaining the edge of the resin RS in the intended position, such that the film HRS may be accurately disposed and developed in the intended position. In such an embodiment, the intended position of the film HRS is determined in advance, and then the protrusions PR may be disposed in the relevant position.

After forming the film HRS by curing the resin RS, the subsequent process may be performed. While the subsequent processes are performed, the film HRS may protect the surface of the display substrate 3.

Referring to FIG. 15G, after the subsequent processes are performed, the film HRS may be removed.

The film HRS may be attached to the protrusions PR while cured. Accordingly, when removing the film HRS from the surface of the display substrate 3, the protrusions PR may be removed together with the film HRS. In an embodiment, the film HRS may be separated from the surface of the display substrate 3 by applying external force to the film HRS, and the protrusions PR may be separated from the surface of the display substrate 3 integrally with the film HRS. Although FIG. 15G shows an embodiment where all protrusions PR are separated from the surface of the display substrate 3 together with the film HRS, the disclosure is not necessarily limited thereto. In another embodiment, some of the protrusions PR may be removed together with the film HRS, and others may remain on the display substrate 3.

Coating traces MK may remain where the protrusions PR are removed together with the film HRS. The coating traces MK may have a band shape extending in a direction in which the protrusions PR are arranged. Accordingly, the coating traces MK may extend along the edge of the display substrate 3 and at least partially surround the display area DA. These coating traces MK may remain on the display substrate 3 and may also remain on the display apparatus, which is the final product.

In an embodiment of the disclosure, as described above, the protrusions PR are disposed on the upper surface of the input-sensing layer 20. However, the disclosure is not limited thereto. In another embodiment, the protrusions PR may be disposed on the image generating layer 10 and disposed on another layer disposed on the input-sensing layer 20. That is, the protrusions PR is variously applicable under situations in which the resin is desired to be applied for the purpose of protection of the display substrate in a preset operation of the process of manufacturing the display apparatus.

According to an embodiment, the display substrate includes the protrusions configured to control flowing of the resin when disposing the resin. According to an embodiment, a method of manufacturing the display apparatus, includes disposing the protrusions on the display substrate and disposing the resin to form the protective film.

In such an embodiment, when applying the liquid (or resin) protective film, an accuracy of the area in which the resin is developed may be improved. Accordingly, the display substrate may be more precisely protected during the process, and the quality of the display apparatus may be improved.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display substrate comprising:
a substrate including a display area and a peripheral area surrounding the display area;
a plurality of light-emitting diodes arranged in the display area over the substrate;
a thin-film encapsulation layer covering the plurality of light-emitting diodes; and
a plurality of protrusions arranged in the peripheral area on the thin-film encapsulation layer,
wherein the plurality of protrusions are arranged along at least a portion of edges of the display area.

2. The display substrate of claim 1, further comprising a resin disposed on the thin-film encapsulation layer and overlapping the display area.

3. The display substrate of claim 2, wherein the resin is in direct contact with at least one of the plurality of protrusions.

4. The display substrate of claim 2, wherein the plurality of protrusions are apart from each other, and a portion of an edge of the resin is between two adjacent protrusions among the plurality of protrusions.

5. The display substrate of claim 1, wherein the substrate includes an opening area inside the display area and an intermediate area between the opening area and the display area,
wherein the intermediate area at least partially surrounds the opening area, and
wherein the display substrate further includes a plurality of additional protrusions disposed on the thin-film encapsulation layer in the intermediate area.

6. The display substrate of claim 1, further comprising an input-sensing layer disposed on the thin-film encapsulation layer and including an electrode layer and an insulating layer, wherein the plurality of protrusions are disposed on the input-sensing layer.

7. The display substrate of claim 1, wherein the thin-film encapsulation layer includes:
a first inorganic encapsulation layer covering the plurality of light-emitting diodes;
an organic encapsulation layer disposed on the first inorganic encapsulation layer; and
a second inorganic encapsulation layer covering the organic encapsulation layer.

8. The display substrate of claim 7, wherein the plurality of protrusions are arranged outside a region in which the organic encapsulation layer is arranged.

9. A method of manufacturing a display apparatus, the method comprising:
preparing a display substrate including a plurality of light-emitting diodes arranged in a display area and a thin-film encapsulation layer covering the plurality of light-emitting diodes;
disposing a plurality of protrusions on the thin-film encapsulation layer in a peripheral area surrounding the display area; and
disposing a resin on the display substrate to overlap the display area.

10. The method of claim 9, wherein the plurality of protrusions are arranged along an edge of the display area.

11. The method of claim 9, wherein the plurality of protrusions are apart from each other.

12. The method of claim 9, further comprising causing the resin to flow toward the plurality of protrusions.

13. The method of claim 12, wherein an edge of a region in which the resin is arranged is defined by the plurality of protrusions.

14. The method of claim 13, further comprising curing the resin.

15. The method of claim 14, wherein, during the curing of the resin, the edge of the region in which the resin is arranged is fixed and maintained by the plurality of protrusions.

16. The method of claim 14, further comprising separating the cured resin together with at least one of the plurality of protrusions from the display substrate.

17. The method of claim 9, wherein the display substrate includes an opening area inside the display area and an intermediate area between the opening area and the display area, the intermediate area at least partially surrounding the opening area, and
wherein the method further includes disposing a plurality of additional protrusions on the thin-film encapsulation layer in the intermediate area.

18. The method of claim 9, further comprising disposing an input-sensing layer on the thin-film encapsulation layer, wherein the disposing the plurality of protrusions includes disposing the plurality of protrusions on the input-sensing layer on the thin-film encapsulation layer.

19. A method of manufacturing an electronic apparatus, the method comprising:
manufacturing a display apparatus; and
disposing the display apparatus in a housing, wherein
manufacturing the display apparatus comprises:
preparing a display substrate including a plurality of light-emitting diodes arranged in a display area and a thin-film encapsulation layer covering the plurality of light-emitting diodes;
disposing a plurality of protrusions on the thin-film encapsulation layer in a peripheral area surrounding the display area; and
disposing a resin on the display substrate to overlap the display area.

20. The method of claim 19, further comprising:
disposing an electronic element in the housing.
